(19) United States
(12) Patent Application Publication
(10) Pub. No.: US 2020/0303158 A1
(43) Pub. Date: Sep. 24, 2020

(54) ELECTRON BEAM INSPECTION TOOL AND METHOD FOR POSITIONING AN OBJECT TABLE

(71) Applicant: ASML Netherlands B.V., Veldhoven (NL)

(72) Inventors: Niels Johannes Maria Bosch, Venlo (NL); Peter Paul Hempenius, Nuenen (NL); Sven Antoin Johan HOL, Sint Oedenrode (NL); Marcel Koenrood Marie Baggen, Nuenen (NL)

(21) Appl. No.: 16/870,747

(22) Filed: May 8, 2020

Related U.S. Application Data
(63) Continuation of application No. PCT/EP2018/080135, filed on Nov. 5, 2018.

(30) Foreign Application Priority Data
Nov. 10, 2017 (EP) 17201087.8

(51) Int. Cl. H01J 37/20; H01J 37/09; H01J 37/304

(52) U.S. Cl. CPC H01J 37/20; H01J 37/09; H01J 2237/20278; H01J 2237/0264; H01J 2237/26; H01J 37/3045

(57) ABSTRACT

The invention relates to a particle beam apparatus comprising:
a particle beam source configured to generate a particle beam;
a magnetic coil configured to emit a magnetic field to manipulate the particle beam;
an object table configured to hold a substrate;
a positioning device comprising ferromagnetic material, the positioning device further comprising at least one motor configured to position the object table with respect to the particle beam; and
a controller configured to provide a control signal to the at least one motor to at least partly compensate for a magnetic force induced by the magnetic field acting on the positioning device.

### CROSS-REFERENCE TO RELATED APPLICATIONS

This application claims priority to International Application No. PCT/EP2018/080135, filed Nov. 5, 2018, and published as WO 2019/091903 A1, which claims priority of EP application 17201087.8 which was filed on Nov. 10, 2017. The contents of these applications are incorporated herein by reference in their entireties.

### TECHNICAL FIELD

The embodiments of the present disclosure relate to an electron beam (e-beam) inspection tool and a method for positioning an object table.

### BACKGROUND ART

In the semiconductor processes, defects are inevitably generated. Such defects may impact device performance even up to failure. Device yield may thus be impacted, resulting in cost raise. In order to control semiconductor process yield, defect monitoring is important. One tool useful in defect monitoring is SEM (Scanning Electron Microscope) which scans a target portion of a specimen using one or more beams of electrons.

For focusing the e-beam, an electron optics system is provided, which comprises a magnetic coil that is arranged above the wafer that is to be inspected. By changing a current through the coil, the focal point of the e-beam may be adjusted in order to focus the beam onto the surface of the wafer. The device may comprise further magnetic coils that emit a magnetic field for controlling a position of the beam on the substrate by bending of the beam.

### SUMMARY

The embodiments of the present disclosure provide a particle beam apparatus with enhanced positioning of the positioning device. This object is achieved in the embodiments of the apparatus, method and computer program as described in this document.

So according to some embodiments of the present disclosure, there is provided a particle beam apparatus comprising:

a particle beam source configured to generate a particle beam;
a magnetic coil configured to emit a magnetic field to manipulate the particle beam; an object table configured to hold a substrate;
a positioning device comprising ferromagnetic material, the positioning device further comprising at least one motor configured to position the object table with respect to the particle beam; and
a controller configured to provide a control signal to the at least one motor to compensate for a magnetic force induced by the magnetic field acting on the positioning device.

According to some embodiments of the present disclosure, there is provided a method for positioning an object table of an particle beam apparatus, comprising the steps of:

providing, with a controller, a control signal to compensate for a magnetic force induced by a magnetic field acting on a positioning device for positioning the object table, the magnetic field at least partly emitted from a magnetic lens of the particle beam apparatus,
actuating at least one motor of the positioning device at least partly based on the control signal.

Further aspect of the disclosed embodiments may be embodied by a particle beam apparatus, an e-beam apparatus, or an e-beam inspection apparatus.

### BRIEF DESCRIPTION OF THE DRAWINGS

The embodiments of the present disclosure will be readily understood by the following detailed description in conjunction with the accompanying drawings, wherein like reference numerals designate like structural elements, and in which:

FIGS. 1A and 1B are schematic illustrations of an e-beam inspection tool according to some embodiments of the present disclosure.

FIGS. 2 and 3 are schematic illustrations an electron optical system as can be applied in some embodiments of the present disclosure.

FIG. 4 schematically depicts a possible control architecture of an EBI system according to some embodiments of the present disclosure.

FIG. 5 schematically depicts a side view on an embodiment of the e-beam inspection tool according to some embodiments of the present disclosure.

FIG. 6 schematically depicts a block scheme with a control loop of the e-beam inspection tool, according to some embodiments of the present disclosure.

FIG. 7A schematically depicts a horizontal magnetic reluctance force acting on an object table of the tool, as function of the position of the object table.

FIG. 7B schematically depicts a vertical magnetic reluctance force acting on an object table of the tool, as function of the position of the object table.

While the disclosed embodiments are susceptible to various modifications and alternative forms, specific embodiments thereof are shown by way of example in the drawings and may herein be described in detail. The drawings may not be to scale. It should be understood, however, that the drawings and detailed description thereto are not intended to limit the embodiments to the particular form disclosed, but on the contrary, the intention is to cover all modifications, equivalents and alternatives falling within the spirit and scope of the disclosed embodiments as defined by the appended claims.

### DETAILED DESCRIPTION OF EXAMPLE EMBODIMENTS

The electron optics system with the magnetic coil has the drawback that the magnetic field from the coil is also emitted towards the positioning device, such that a magnetic reluctance force acts on the positioning device, and in particular on ferromagnetic components of the positioning device, such as the at least partially ferromagnetic shielding. As a result, the position of the object table on the positioning device is disturbed by the magnetic reluctance force, and eddy currents induce a damping effect on the positioning device, when it is moving. To compensate for these disturbances, the settling time of the positioning device, after the object table has been moved, may be increased. This, however, has the result that the throughput of the inspection tool is decreased.

Various example embodiments of the present disclosure will now be described more fully with reference to the accompanying drawings in which some example embodiments are shown. In the drawings, the thicknesses of layers and regions may be exaggerated for clarity.

Detailed illustrative embodiments of the present disclosure are disclosed herein. However, specific structural and functional details disclosed herein are merely representative of purposes of describing example embodiments of the present disclosure. These embodiments may, however, may be embodied in many alternate forms and should not be construed as limited to only the embodiments set forth herein.

Accordingly, while example embodiments of the present disclosure are capable of various modifications and alternative forms, embodiments thereof are shown by way of example in the drawings and will herein be described in detail. It should be understood, however, that there is no intent to limit example embodiments of the present disclosure to the particular forms disclosed, but on the contrary, example embodiments of the present disclosure are to cover all modifications, equivalents, and alternatives falling within the scope of the disclosure. Like numbers refer to like elements throughout the description of the figures.

As used herein, the term “specimen” generally refers to a wafer or any other specimen on which defects of interest (DOI) may be located. Although the terms “specimen” and “sample” are used interchangeably herein, it is to be understood that embodiments described herein with respect to a wafer may configured and/or used for any other specimen (e.g., a reticle, mask, or photomask).

As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

In this present disclosure, “axial” means “in the optical axis direction of an apparatus, column or a device such as a lens”, while “radial” means “in a direction perpendicular to the optical axis”. Usually, the optical axis starts from the cathode and ends at specimen. The optical axis always refers to z-axis in all drawings.

The term, crossover, refers to a point where the electron beam is focused.

The term, virtual source, means the electron beam emitted from the cathode can be traced back to a “virtual” source.

The inspection tool according to the present disclosure relates to a charged particle source, especially to an e-beam source which can be applied to a SEM, an e-beam inspection tool, or an EBDW (E-Beam Direct Writer). The e-beam source, in this art, may also be referred to as an e-gun (Electron Gun).

With respect to the drawings, it is noted that the figures are not drawn to scale. In particular, the scale of some of the elements of the figures may be greatly exaggerated to emphasize characteristics of the elements. It is also noted that the figures are not drawn to the same scale. Elements shown in more than one figure that may be similarly configured have been indicated using the same reference numerals.

In the drawings, relative dimensions of each component and among every component may be exaggerated for clarity. Within the following description of the drawings the same or like reference numbers refer to the same or like components or entities, and only the differences with respect to the individual embodiments are described.

Accordingly, while example embodiments of the present disclosure are capable of various modifications and alternative forms, embodiments thereof are shown by way of example in the drawings and will herein be described in detail. It should be understood, however, that there is no intent to limit example embodiments of the present disclosure to the particular forms disclosed, but on the contrary, example embodiments of the present disclosure are to cover all modifications, equivalents, and alternatives falling within the scope of the disclosure.

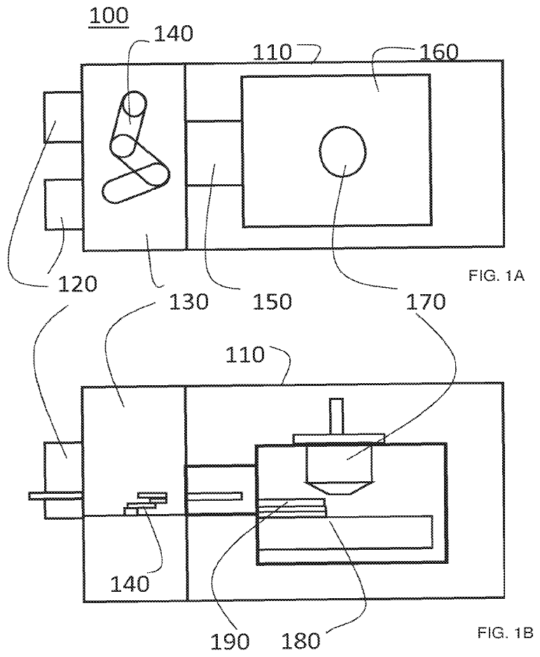

FIGS. 1A and 1B schematically depict a top view and a cross-sectional view of an electron beam (e-beam) inspection (EBI) system 100 according to some embodiments of the present disclosure. The example as shown comprises an enclosure 110, a pair of load ports 120 serving as an interface to receive objects to be examined and to output objects that have been examined. The example as shown further comprises an object transfer system, referred as an EFEM, equipment front end module 130, that is configured to handle and/or transport the objects to and from the load ports. In the example as shown, the EFEM 130 comprises a handler robot 140 configured to transport objects between the load ports and a load lock 150 of the EBI system 100. The load lock 150 is an interface between atmospheric conditions occurring outside the enclosure 110 and in the EFEM and the vacuum conditions occurring in a vacuum chamber 160 of the EBI system 100. In the example as shown, the vacuum chamber 160 comprises an electron optics system 170 configured to project an e-beam onto an object to be inspected, e.g. a semiconductor substrate or wafer. The EBI system 100 further comprises a positioning device 180 that is configured to displace the object 190 relative to the e-beam generated by the electron optics system 170.

In some embodiments, the positioning device may comprise a cascaded arrangement of multiple positioners such an XY-stage for positioning the object in a substantially horizontal plane, and a Z-stage for positioning the object in the vertical direction.

In some embodiments, the positioning device may comprise a combination of a coarse positioner, configured to provide a coarse positioning of the object over comparatively large distances and a fine positioner, configured to provide a fine positioning of the object over comparatively small distances.

In some embodiments, the positioning device 180 further comprises an object table for holding the object during the inspection process performed by the EBI system 100. In such examples, the object 190 may be clamped onto the object table by means of a clamp such as an electrostatic clamp. Such a clamp may be integrated in the object table.

In accordance with the present disclosure, the positioning device 180 comprises a first positioner for positioning the object table and a second positioner for positioning the first positioner and the object table. In addition, the positioning device 180 as applied in the e-beam inspection tool 100 according to the present disclosure comprises a heating device that is configured to generate a heat load in the object table.

The positioning device 180 and heating device as applied in the present disclosure will be discussed in more detail below.

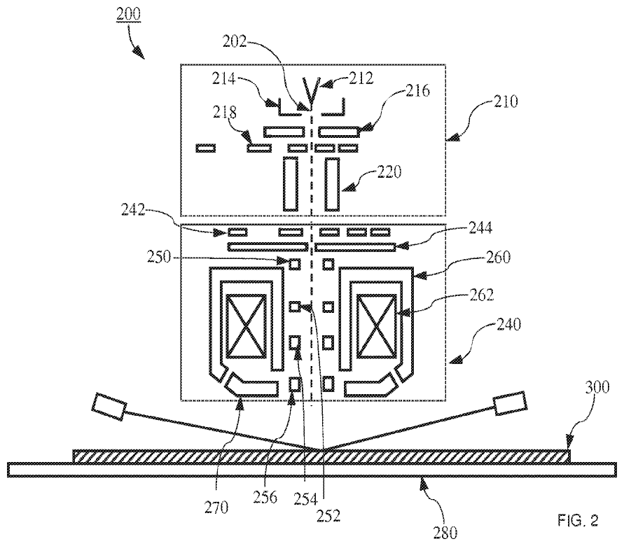

FIG. 2 schematically depict an example of an electron optics system 200 as can be applied in e-beam inspection tool or system according to some embodiments of the present disclosure. The electron optics system 200 comprises an e-beam source, referred to as the electron gun 210 and an imaging system 240.

The electron gun 210 comprises an electron source 212, suppressor 214, an anode 216, a set of apertures 218, and a condenser 220. The electron source 212 can be a Schottky emitter. More specifically, the electron source 212 includes a ceramic substrate, two electrodes, a tungsten filament, and a tungsten pin. The two electrodes are fixed in parallel to the ceramic substrate, and the other sides of the two electrodes are respectively connected to two ends of the tungsten filament. The tungsten is slightly bended to form a tip for placing the tungsten pin. Next, a ZrO2 is coated on the surface of the tungsten pin, and is heated to 1300° C. so as to be melted and cover the tungsten pin but uncover the pinpoint of the tungsten pin. The melted ZrO2 can make the work function of the tungsten lowered and decrease the energy barrier of the emitted electron, and thus the electron beam 202 is emitted efficiently. Then, by applying negative electricity to the suppressor 214, the electron beam 202 is suppressed. Accordingly, the electron beam having the large spread angle is suppressed to the primary electron beam 202, and thus the brightness of the electron beam 202 is enhanced. By the positive charge of the anode 216, the electron beam 202 can be extracted, and then the Coulomb's compulsive force of the electron beam 202 may be controlled by using the tunable aperture 218 which has different aperture sizes for eliminating the unnecessary electron beam outside of the aperture. In order to condense the electron beam 202, the condenser 220 is applied to the electron beam 202, which also provides magnification. The condenser 220 shown in the FIG. 2 may e.g. be an electrostatic lens which can condense the electron beam 202. On the other hand, the condenser 220 can be also a magnetic lens.

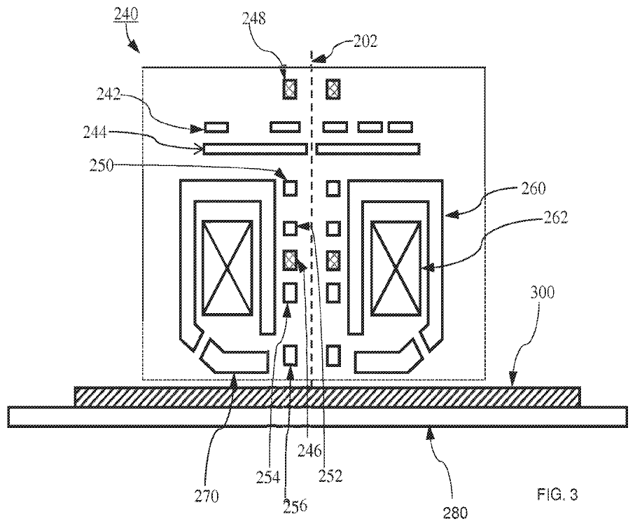

The imaging system 240 as shown in FIG. 3 comprises a blanker 248, a set of apertures 242, a detector 244, four sets of deflectors 250, 252, 254, and 256, a pair of coils 262, a yoke 260, a filter 246, and an electrode 270. The electrode 270 is used to retard and deflect the electron beam 202, and further has electrostatic lens function due to the combination of upper pole piece and sample 300. Besides, the coil 262 and the yoke 260 are configured to the magnetic objective lens.

The electron beam 202, described above, is generated by heating the electron pin and applying the electric field to anode 216, so that, in order to stabilize the electron beam 202, there must be a long time for heating the electron pin. For a user end, it is surely time consuming and inconvenient. Hence, the blanker 248 is applied to the condensed electron beam 202 for temporally deflecting the electron beam 202 away from the sample rather than turning off it.

The deflectors 250 and 256 are applied to scan the electron beam 202 to a large field of view, and the deflectors 252 and 254 are used for scanning the electron beam 202 to a small field of view. All the deflectors 250, 252, 254, and 256 can control the scanning direction of the electron beam 202. The deflectors 250, 252, 254, and 256 can be electrostatic deflectors or magnetic deflectors. The opening of the yoke 260 is faced to the sample 300, which immerses the magnetic field into the sample 300. On the other hand, the electrode 270 is placed beneath the opening of the yoke 260, and therefore the sample 300 will not be damaged. In order to correct the chromatic aberration of the electron beam 202, the retarder 270, the sample 300, and the upper pole piece form a lens to eliminate the chromatic aberration of the electron beam 202.

Besides, when the electron beam 202 bombards into the sample 300, a secondary electron will be emanated from the surface of the sample 300. Next the secondary electron is directed to the detector 244 by the filter 246.

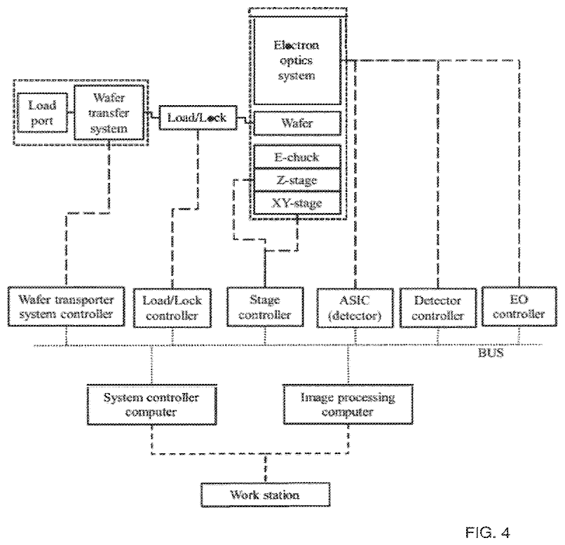

FIG. 4 schematically depicts a possible control architecture of an EBI system according to some embodiments of the present disclosure. As indicated in FIG. 1, the EBI system comprises a load lock, a wafer transfer system, a load/lock, an electron optics system and a positioning device, e.g. including a z-stage and an x-y stage. As illustrated, these various components of the EBI system may be equipped with respective controllers, i.e., a wafer transporter system controller connected to the wafer transfer system, a load/lock controller, an electron optics controller, a detector controller, a stage controller. These controllers may e.g. be communicatively connected to a system controller computer and an image processing computer, e.g. via a communication bus. In the example as shown, the system controller computer and the image processing computer may be connected to a workstation.

The load port loads a wafer to the wafer transfer system, such as EREM 130, and the wafer transfer system controller controls the wafer transfer to transfer the wafer to the load/lock, such as load lock 150. The load/lock controller controls the load/lock to the chamber, such that an object that is to be examiner, e.g. a wafer can be fixed on a clamp, e.g. an electrostatic clamp, also referred to as an e-chuck. The positioning device, e.g. the z-stage and the x-y stage, enable the wafer to move by the stage controller. In some embodiments, a height of the z-stage may e.g. be adjusted using a piezo component such as a piezo actuator. The electron optic controller may control all the conditions of the electron optics system, and the detector controller may receive and convert the electric signals from the electron optic system to image signals. The system controller computer is to send the commands to the corresponding controller. After receiving the image signals, the image processing computer may process the image signals to identify defects.

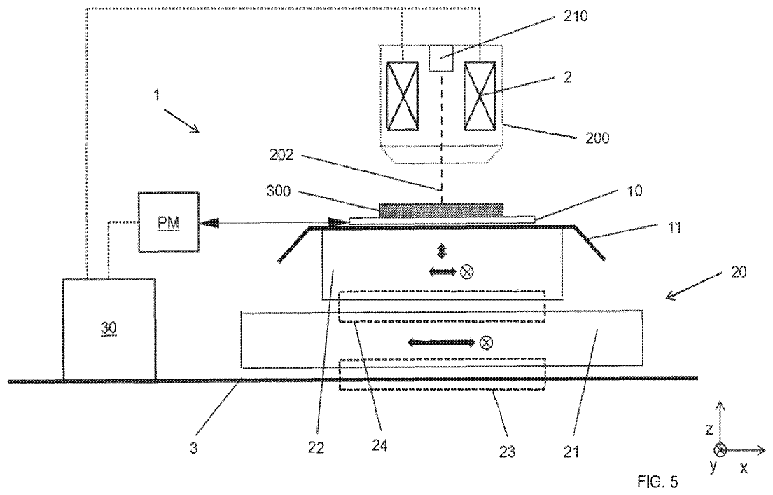

FIG. 5 schematically depicts an example of an e-beam inspection tool 1 according to some embodiments of the present disclosure, referred to with reference numeral 1. The e-beam inspection tool 1 comprises an electron optics system 200, which comprises an electron gun 210 as an e-beam source for generating an e-beam 202 and for transmitting the e-beam 202 towards a substrate 300.

The e-beam inspection tool 1 comprises, in the electron optics system 200, a magnetic coil 2 for focusing the e-beam 202. The magnetic coil 2 is arranged around the e-beam 202 and is located above the substrate 300. During use of the magnetic coil 2, an electric current runs through the coil 2, which causes the coil 2 to emit a magnetic field. The electrons in the e-beam 202 are negatively charged and are thus influenced by the magnetic field that is emitted by the coil 2. By changing the current through the coil 2, the emitted magnetic field changes accordingly and the influence on the e-beam 202, under the influence of the magnetic field, is changed as well. By changing the magnetic field, the e-beam 202 may be focused.

The e-beam inspection tool 1 further comprises an object table 10 to hold the substrate 300 during the inspection with the e-beam 202. The object table 10 is supported by a positioning device 20 and is, with the positioning device 20, movable in a first horizontal direction (x), in a second horizontal direction (y), perpendicular to the first horizontal direction (x), and in a vertical direction (z), which is perpendicular to the first and second horizontal directions (x, y) and which is parallel to the optical axis of the tool 1.

The positioning device 20 is adapted to move the object table 10 with respect to the e-beam 202 in order to align a target portion of the substrate 300 with the e-beam 202. The positioning device 20 comprises a long stroke stage 21 and a short stroke stage 22. The object table 10 is supported by the short stroke stage 22 and the short stroke stage 22 is, in turn, supported by the long stroke stage 21, which is, in turn, supported by a frame 3 of the tool 1.

The positioning device may, in an alternative example, comprise a single stage for positioning the substrate with respect to the beam.

The long stroke stage 21 comprises at least one motor 23 for moving the short stroke stage 22 in the first horizontal direction (x) and in the second horizontal direction (y), as is indicated in FIG. 5 by means of the arrows. The at least one motor 23 is an electromagnetic motor, of which a movable part is movable with respect to a stationary part, under the influence of a magnetic field. The at least one motor 23 is, for example, a Lorentz-type actuator.

The short stroke stage 22 comprises at least one motor 24 for moving the object table 10, with respect to the long stroke stage 21, in the horizontal plane (x, y) and in the vertical direction (z). For example, multiple motors 24 may be provided to position the object table 10 in six degrees of freedom.

In an alternative example, the short stroke stage further comprises a piezo actuator for moving the object table in the vertical direction.

The long stoke stage 21 and the short stroke stage 22 are both adapted to move the object table 10 in the first horizontal direction (x) and the second horizontal direction (y), perpendicular to the first horizontal direction (x). Together, the long stoke stage 21 and the short stroke stage 22 form an x-y stage for moving the object table 10 in the horizontal plane.

The short stroke stage 22 is further adapted to move the object table 10 in the vertical direction (z), perpendicular to the horizontal directions (x, y). The short stroke stage 22 thereby also forms a z-stage of the e-beam inspection tool 1 for moving the object table 10 in the vertical direction (z).

Between the object table 10 and the short stroke stage 22, a shielding 11 is provided. The shielding 11 is made at least partially from a ferromagnetic material, such as mu-metal, to shield any magnetic field that is emitted by the motors (23, 24) of the positioning device 20 in order to prevent this motor magnetism from influencing and deflecting the e-beam 202. The shielding 11 is connected to the object table 10 and is therefore movable together with the object table 10.

The ferromagnetic shielding 11 is arranged in the vicinity of the magnetic coil 2 and is, although it prevents motor magnetism form reaching the e-beam 202, subjected to the magnetic field that is emitted by the coil 2. Similarly, other at least partially ferromagnetic components of the positioning device 20 may also be subjected to the magnetic field from the coil 2.

The interaction between the magnetic field from the coil 2 and the ferromagnetic components gives rise to magnetic forces that act between them. An example of such a force is a magnetic reluctance force, which results from the magnetic attraction between the magnetic coil 2 and the ferromagnetic component. A second example is a magnetic damping force, dependent on a relative velocity between the coil 2 and the ferromagnetic component, which is induced by eddy currents.

In some embodiments, tool 1 further comprises a control unit 30 for controlling the position of the object table 10 with respect to the e-beam 202. The control unit 30 is adapted to move the object table 10 to a desired position with respect to the e-beam 202 and is further adapted to compensate for magnetic disturbance forces such as magnetic reluctance forces and/or magnetic damping forces that act on the object table 10.

The control unit 30 may be a separate processing device, or may be implemented on a central processing device of the e-beam inspection tool 1. The control unit 30 is for example a computer device or integrated in a computer device.

In some embodiments, e-beam inspection tool 1 is adapted to move the object table 10 in a stepwise manner. This means that the object table 10 is moved in a plurality of successive positions, such that in each respective position of the object table 10, a target portion on the substrate 300 may be inspected with the e-beam 202, while the object table 10 is in a stationary position. In some embodiments, the control unit 30 may be adapted to move the object table 10 in a scanning movement, while the respective target portion is inspected by the e-beam 202 during this scanning movement.

The control unit 30 is connected to the electron optics system 200, in order to control the magnetic coil 2 of the tool 1. The control unit 30 is further arranged to control the motors (23, 24) of the positioning device 20. The control unit 30 is also connected to a position measurement system (PM), adapted to measure an actual position of the object table 10. In FIG. 5, all of these connections with the control unit 30 are indicated by means of dashed lines.

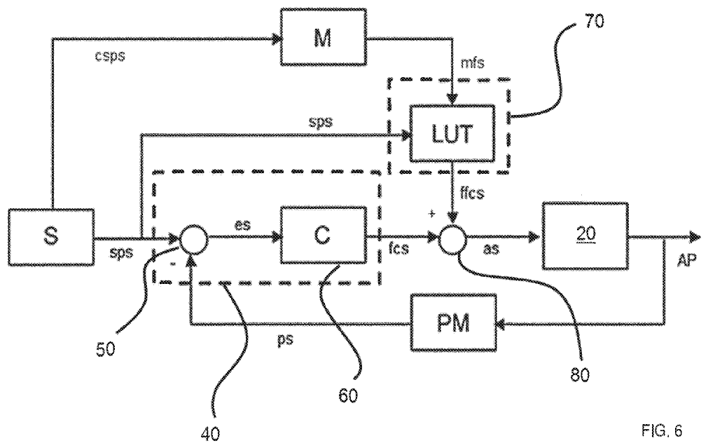

In FIG. 6, a control scheme is shown, which depicts a control loop with which the position of the object table 10 is controlled.

The control unit 30 comprises a set-point generator (S) that is adapted to provide a set-point signal (sps). The set-point signal (sps) is representative for a desired position of the object table 10. The desired position of the object table 10 is the position in which the substrate 300 is to be brought to be inspected with the e-beam 202.

During use of the e-beam inspection tool 1, the control unit 30 may select multiple desired positions in which the object table 10 must be brought subsequently. As such, the substrate 300 will be inspected at multiple subsequent positions.

The position measurement system (PM) is arranged to measure an actual position (ap) of the object table 10 and to transmit a position signal (ps) that is representative for the actual position (ap) of the object table 10. The position measurement system (PM) is, for example, an interferometer-based position measurement system. Alternatively, the position measurement system may, for example, be an encoder-based position measurement system.

The control unit 30 comprises a feedback device 40 to provide, on the basis of the position signal (ps) and the set-point signal (sps), a feedback control signal (fcs). The feedback device 40 comprises a comparator 50, to compare the position signal (ps) with the set-point signal (sps). The comparator 50 is adapted to subtract the position signal (ps) from the set-point signal (sps), in order to obtain an error signal (es) that is representative for a difference between the actual position (ap) of the object table 10 and the desired position of the object table 10.

The feedback device 40 further comprises a position feedback controller 60 to provide, on the basis of the error signal (es), the feedback control signal (fcs). The feedback control signal (fcs) is thereby representative for an actuation force to be exerted on the object table 10 to move the object table 10 from the actual position (ap) towards the desired position.

As described in a later paragraph, the positioning control of the object table 10 can also be performed by feedforward control. It must be clear to the skilled person that the poisoning control of the object table 10 is not necessarily feedback control. Therefore, the feedback device and the feedback control signal (fcs) are also referred to as a further controller and a further control signal, respectively, later in this application.

The magnetic coil 2 comprises a controller (M), which is, in the present embodiment incorporated in the control unit 30. In some embodiments, the controller (M) may be arranged in another processing device. The controller (M) is adapted to control the coil 2 to emit the magnetic field and to transmit a magnetic field signal (mfs), which is representative for a parameter of the coil 2. The parameter of the coil 2 is for example a magnitude of the emitted magnetic field, which is linearly dependent on the electric current through the coil 2. The transmitted magnetic field signal (mfs) may, for example, increase quadratic with the magnitude of the magnetic field and with the current through the coil 2.

The controller (M) is connected to the set-point generator (S). The set-point generator (S) is adapted to provide a coil set-point signal (csps) to the controller (M), which signal (csps) is representative for a required magnetic field to be emitted by the coil 2. The coil set-point signal (csps) is for example a current to be guided through the magnetic coil 2. During use, the controller (M) may, for example, control the coil 2 on the basis of the control set-point signal (csps) and may, for example, transmit the magnetic field signal (mfs) that is representative for the emitted magnetic field. It should be clear to the skilled person that the coil set-point signal (csps) may come from any other set-point generator, for example, physically separated from the set-point generator (S).

The control unit 30 further comprises a feedforward device 70 to provide, on the basis of the set-point signal (sps), a feedforward control signal (ffcs). The feedforward control signal (ffcs) is a signal that is representative for a force to compensate the magnetic reluctance force of the magnetic field that acts on the ferromagnetic components of the positioning device 20, and in particular on the at least partially ferromagnetic shielding 11. Alternatively, or in addition to the set-point signal (sps), the feedforward device 70 may be adapted to provide the feedforward control signal (ffcs) on the basis of a derivative of the set-point signal (sps) in order to compensate for magnetic damping forces that are induced by eddy currents, during relative movement of the ferromagnetic components with respect to the magnetic field. It should be clear to the skilled person that the compensation of the magnetic force may not necessarily be performed in a feedforward manner. Therefore, the feedforward device and the feedforward control signal (ffcs) are also referred to as a controller and a control signal, respectively, later in this application.

Alternatively, or in addition to the set-point signal (sps) and/or the derivative of the set-point signal (sps), the feedforward device 70 may be adapted to provide the feedforward control signal (ffcs) on the basis of the position signal (ps) of the object table 10 or a derivative of the position signal.

The feedforward device 70 is further adapted to determine the feedforward control signal (ffcs) on the basis of the magnetic field signal (mfs) that is provided by the controller (M) of the magnetic coil 2, because the magnitude of the emitted magnetic field influences the occurring magnetic disturbance forces such as magnetic reluctance forces and/or magnetic damping forces.

When the magnetic field is relatively strong, the magnetic disturbance forces such as magnetic reluctance forces and/or magnetic damping forces will be relatively strong as well. When, however, the magnetic field is relatively weak, the magnetic disturbance forces will be relatively weak as well. It has, in particular, been found that the magnetic reluctance force of the magnetic field on the ferromagnetic components of the positioning device 20 scales quadratic with the magnitude of the emitted magnetic field and the electric current through the magnetic coil 20.

In some embodiments, the feedforward device 70 comprises a lookup table (LUT), stored in a data storage, in which set-point signals (sps), the position signal (ps), and/or magnetic field signals (mfs) are stored, together with associated feedforward control signals (ffcs). The lookup table (LUT) may, for example, comprise a set of two-dimensional tables or a single multiple dimensional table such as a three-dimensional table. Any other configuration of lookup tables may also be used. During use of the e-beam inspection tool 1, the lookup table (LUT) is adapted recall and transmit a respective feedforward control signal (ffcs) upon input of a certain set-point signal (sps), representative for a desired position of the object table 10, of a certain position signal (ps), representative for an actual position of the object table 10, and of a certain magnetic field signal (mfs), representative for a parameter of the emitted magnetic field.

In some embodiments, the set-point signals (sps), the position signals (ps), and/or magnetic field signals (mfs) are stored with feedforward control signals (ffcs) in the lookup table (LUT) by means of a method that will be described below. Preferably, the signals (sps, ps, mfs, ffcs) are stored in the lookup table (LUT) during initialization and calibration of the tool 1. Alternatively, however, the set-point signals (sps), position signals (ps), magnetic field signals (mfs) and feedforward control signals (ffcs) may be pre-set in the lookup table (LUT) of the tool 1.

In some embodiments, the feedforward device comprises a functional relationship between the set-point signal and the feedforward control signal. Alternatively, or in addition to the set-point signal, the functional relationship may also comprise a functional relationship between a derivative of the set-point signal and the feedforward control signal. This provides an advantage that not all feedforward control signals need to be stored in the feedforward device, together with associated set-point signals, but that the feedforward device is adapted to calculate a feedforward control signal on the basis of a set-point signal and/or a derivative of the set-point signal that is imported in the feedforward device.

Alternatively, or in addition to the set-point signal (sps), the functional relationship may be configured to provide a relationship between the position signal (ps) and the feedforward control signal. Alternatively, or in addition to the set-point signal, the functional relationship may also comprise a relationship between a derivative of the position signal and the feedforward control signal. In this case, the feedforward device is adapted to calculate a feedforward control signal on the basis of a position signal and/or a derivative of the position signal that is imported in the feedforward device.

In some embodiments, the functional relationship in the feedforward device is a functional relationship between the set-point signal, a derivative of the set-point signal, and/or magnetic field signal and the feedforward control signal. In this example, the feedforward device is adapted to calculate a feedforward control signal on the basis of a set-point signal, a derivative of the set-point signal, and/or a magnetic field signal that are fed into the feedforward device.

Alternatively, or in addition to the set-point signal (sps), the functional relationship in the feedforward device is a relationship between the position signal, a derivative of the position signal, and/or, magnetic field signal and the feedforward control signal. In this example, the feedforward device is adapted to calculate a feedforward control signal on the basis of a position signal, a derivative of the position signal, and/or a magnetic field signal that are fed into the feedforward device.

The feedforward device 70 may be arranged parallel to a position feedforward device, which is configured to provide a position feedforward signal on the basis of the set-point signal (sps). In some embodiments, the feedforward device and the position feedforward device may be combined to form a single feedforward device.

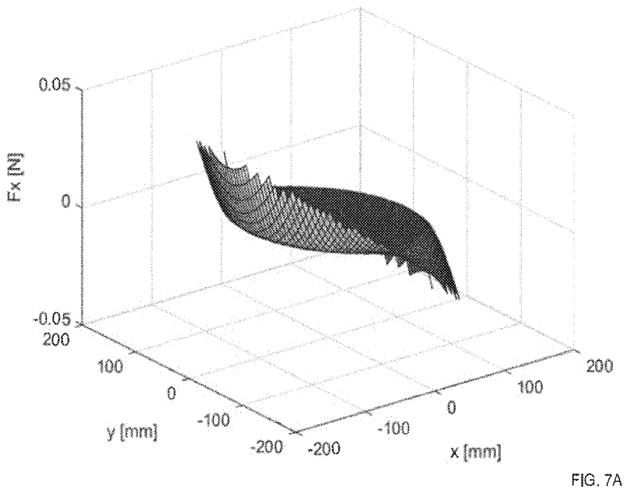

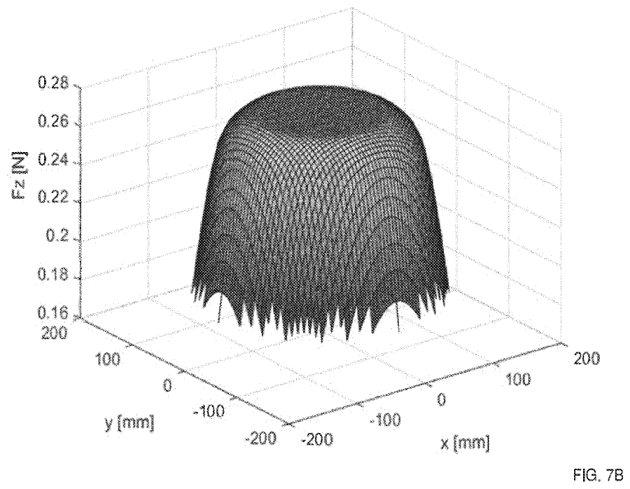

The set-point signal (sps) is representative for the desired position of the object table 10 and the feedforward control signal (ffcs) is representative for the force that is needed to compensate for the magnetic disturbance forces such as magnetic reluctance forces and/or magnetic damping forces. In FIG. 7A, a graphical representation of the functional relationship between the position of the object table 10 and the magnetic reluctance force (Fx) in the first horizontal direction (x) is displayed. Furthermore, FIG. 7B displays a graphical representation of the functional relationship between the position of the object table 10 and the magnetic reluctance force (Fz) in the vertical direction (z).

For calculating the functional relationship between the set-point signal and the feedforward control signal, the feedforward device is adapted to calculate the required feedforward control signal to overcome the magnetic disturbance forces for a certain set-point signal, such that a net force on the positioning device becomes zero.

The tool 1 further comprises an addition device 80 that is connected to the feedback device 40 and to the feedforward device 70 for adding the feedback control signal (fcs) and the feedforward control signal (ffcs) to provide an actuation signal (as).

The feedback control signal (fcs), on which the actuation signal (as) is based, is representative for a required force to move the object table 10 towards the desired position. The feedforward control signal (ffcs), on which the actuation signal (as) is based as well, is representative for the required force to compensate for the magnetic disturbance forces that acts on the positioning device 20 and therewith on the object table 10. The actuation signal (as) thereby comprises combined information on both the required force for displacement of the object table 10 and a required compensation for compensating the magnetic disturbance forces.

The addition device 80 is connected to the positioning device 20 to feed the actuation signal (as) into the positioning device 20 to move the object table 10 on the basis of the actuation signal (as).

The positioning of the object table 10 is explained, referring to the control loop that is displayed with the block scheme in FIG. 6. First, a set-point signal (sps) is generated with the set-point generator (S). The set-point signal (sps) is transmitted to the comparator 50 of the feedback device 40 and towards the lookup table (LUT) of the feedforward device 70. A derivative of the set-point signal (sps) may also be transmitted to the lookup table (LUT).

The position signal (ps) is determined with the position measurement device (PM), on the basis of the actual position (ap) of the object table 10. The position signal (ps) is also fed into the comparator 50 of the feedback device 40 and may also be fed into the lookup table (LUT) of the feedforward device 70. A derivative of the position signal (ps) may also be transmitted to the lookup table (LUT).

The comparator 50 subtracts the position signal (ps) from the set-point signal (sps) in order to obtain an error signal (es) that is transmitted towards the position feedback controller 60 of the feedback device 40. The position feedback controller 60 provides, on the basis of the error signal (es), the feedback control signal (fcs), which is fed into the addition device 80.

The controller (M) of the magnetic coil 2 provides the magnetic field signal (mfs) on the basis of the coil set-point signal (csps). The magnetic field signal (mfs) is transmitted towards the lookup table (LUT) of the feedforward device 70 as well.

Upon input of the set-point signal (sps), of the derivative of the set-point signal (sps), of the position signal (ps), of the derivative of the position signal (ps), and/or of the magnetic field signal (mfs), the lookup table (LUT) recalls the feedforward control signal (ffcs) that is associated with the respective signals (sps, the derivative of sps, ps, the derivative of ps, mfs). The feedforward control signal (ffcs) is transmitted towards the addition device 80.

The addition device 80 adds the feedback control signal (fcs) and the feedforward control signal (ffcs) and thereby provides the actuation signal (as), which is fed into the controller (P) of the positioning device 20.

By actuating at least one motor (23, 24) of the positioning device 20 on the basis of the actuation signal (as), the object table 10 is moved towards the desired position.

In the current example, before positioning the object table 10, the set-point signals (sps), the derivative of the set-point signal (sps), the position signal (ps), the derivative of the position signal (ps), and/or the magnetic field signals (mfs), and feedforward control signals (ffcs) are stored in the lookup table (LUT) by means of a method that will be described below. This method may be applied during calibration of the tool 1 and in particular during calibration of the feedforward device 70.

In this method the object table 10 is moved towards a desired position by means of the positioning device 20. The set-point signal (sps) and/or a derivative of the set-point signal (sps) are stored in the lookup table (LUT).

Alternatively or in addition to storing the set-point signal (sps) in the lookup table (LUT), the position signal (ps) representing the actual position (ap) of the object table 10 and/or a derivative of the position signal (ps) are measured by the position measurement system (PM) and stored in the lookup table (LUT).

Then, the magnetic coil 2 is actuated with the controller (M) to emit a magnetic field. The parameter of the magnetic field and/or the electric current through the coil 2 may, at least initially, be any arbitrary parameter and/or current.

After emitting of the magnetic field, the magnetic field signal (mfs) that corresponds to the parameter of the magnetic field and/or the electric current through the coil 2 is determined and stored in the lookup table (LUT) of the feedforward device 70.

Then, the magnetic disturbance force, resulting from the magnetic field acting on the ferromagnetic components of the positioning device 20, is measured. This magnetic disturbance force may, for example, be measured with the at least one motor (23, 24) of the positioning device. Preferably, the magnetic disturbance force is measured in three orthogonal directions, more preferably in the first horizontal direction (x), the second horizontal direction (y) and the vertical direction (z).

Then, the required feedforward control signal (ffcs), to overcome the magnetic disturbance force is calculated. The feedforward control signal (ffcs) is, for example, calculated by means of the control unit 30 of the tool 1 in which a functional relationship between values for the magnetic disturbance force and associated feedforward control signals (ffcs) may be stored.

In some embodiments, the calculated feedforward control signal (ffcs) is stored in the lookup table (LUT) of the feedforward device 70 and associated with the respective set-point signal (sps), the respective derivative of the set-point signal (sps), the respective position signal (ps), the respective derivative of the position signal (ps), and/or the respective magnetic field signal (mfs) that have been stored in the lookup table (LUT) as well. After storing of the feedforward control signal (ffcs), the controller (M) of the magnetic coil 2 may actuate, when desired the coil 2 to emit a second magnetic field that differs from the first magnetic field. Preferably, the coil 2 is controlled to emit a magnetic field that has a different field strength than the field strength of the magnetic field that has been emitted before.

After emitting the second magnetic field, a corresponding magnetic field signal (mfs) is determined and stored in the lookup table (LUT). Furthermore, the magnetic disturbance force of the second magnetic field, acting on the ferromagnetic components of the positioning device 20, is measured and the corresponding feedforward control signal (ffcs) is calculated and stored in the lookup table (LUT).

The above step of emitting a second magnetic field may be repeated multiple times, for various different magnetic fields, in order to calculate a required feedforward control signal (ffcs) for the various magnetic fields with various magnetic field strengths. During use of the tool 1 for positioning the object table 10, the object table 10 may be positioned more accurately in anticipation of various magnetic fields and field strengths, when the inspection of the substrate 300 requires various magnetic fields with various magnetic field strengths to be used.

In some embodiments, the above method is repeated for other desired positions of the object table 10. By doing so, the feedforward control signal (ffcs) is also calculated for the other desired positions in which the object table 10 may be brought for inspection of the substrate 300, such that the magnetic disturbance forces may be compensated in all of these desired positions with other set-point signals (sps).

After repeating the determination of the feedforward control signals (ffcs) for the various magnetic fields and various desired positions, the lookup table (LUT) thus comprises a respective feedforward control signal (ffcs) for a number of combinations between set-point signals (sps), derivatives of the set-point signals (sps), position signal (ps), derivatives of the position signals (ps), and/or magnetic field signals (mfs). The feedforward device 70 may be configured to interpolate values between the stored numbers of combinations.

In some embodiments, the feedforward control signals (ffcs) are not stored in a data storage, such as a lookup table, but are related in the feedforward device by means of a functional relationship between the set-point signal (sps) and/or the derivative of the set-point signal (sps), and the feedforward control signal (ffcs), a functional relationship between the position signal (ps) and/or the derivative of the position signal (ps), and the feedforward control signal (ffcs), and/or a functional relationship between the magnetic field signal (mfs) and the feedforward control signal (ffcs).

After determining the feedforward control signals (ffcs), for each of the set-point signals (sps), for each of the derivatives of the set-point signals (sps), for each of the position signals (ps), for each of the derivatives of the position signals (ps), and/or for each of the magnetic field signals (mfs), the control unit 30 of the tool 1 calculates the functional relationship between them (sps, derivative of sps, ps, derivative of ps, and/or mfs) and their respective feedforward control signals (ffcs). The functional relationship is then stored in the feedforward device such that it is adapted to calculate, upon input of a certain set-point signal (sps), a certain derivative of the set-point signal (sps), a certain position signal (ps), a certain derivative of the position signal (ps), and/or a certain magnetic field signal (mfs), an appropriate feedforward control signal (ffcs).

Further embodiments may be described in the following clauses:
1. A particle beam apparatus comprising:
a particle beam source configured to generate a particle beam;
a magnetic coil configured to emit a magnetic field to manipulate the particle beam; an object table configured to hold a substrate;
a positioning device comprising ferromagnetic material, the positioning device further comprising at least one motor configured to position the object table with respect to the particle beam; and
a controller configured to provide a control signal to the at least one motor to at least partly compensate for a magnetic force induced by the magnetic field acting on the positioning device.
2. The particle beam apparatus according to clause 1, wherein the magnetic force is a magnetic reluctance force induced by the magnetic field and/or a magnetic damping force induced by eddy current.
3. The particle beam apparatus according to clause 1 or 2, wherein the controller is configured to provide the control signal at least partly based on a set-point signal and/or a derivative of the set-point signal, the set-point signal representing a desired position of the object table.
4. The particle beam apparatus according to any preceding clauses, the particle beam apparatus further comprising:
   a further controller configured to provide a further control signal to the at least one motor to position the object table.
5. The particle beam apparatus according to clause 4, wherein the further controller comprises a feed-forward controller and/or a feed-back controller.
6. The particle beam apparatus according to any of the preceding clauses, further comprising
   a position measurement system to provide a position signal representing a position of the object table.
7. The particle beam apparatus according to clause 6, wherein the controller is configured to provide the control signal at least partly based on the position signal and/or a derivative of the position signal.
8. The particle beam apparatus according to clause 6 or 7, wherein the further controller is configured to provide the further control signal at least partly based on a difference between the position signal and a further set-point signal.
9. The particle beam apparatus according to clause 8, wherein the further set-point signal is the same as the set-point signal.
10. The particle beam apparatus according to any of preceding clauses, wherein the controller is configured to provide the control signal at least partly based on a magnetic field signal, the magnetic field signal being representative for a parameter of the magnetic field and/or an electric current through the magnetic coil.
11. The particle beam apparatus of any of clause 3 to 10, wherein the controller comprises a data storage configured to store set-point signals and/or derivatives of the set-point signals together with associated control signals.
12. The particle beam apparatus of any of clause 6 to 11, wherein the controller comprises a further data storage configured to store position signals and/or derivatives of the position signals together with further associated control signals.
13. The particle beam apparatus of any of clause 10 to 12, wherein the controller comprises an even further data storage configured to store magnetic field signals and even further associated control signals.
14. The particle beam apparatus of any of clause 10 to 13, wherein the data storage, the further data storage, or the even further data storage is configured to interpolate values between stored combinations of:
the set-point signals and/or the derivatives of the set-point signals, and the associated control signals;
the position signals and/or the derivatives of the position signals, and the further associated control signals; and/or
the magnetic field signals and the even further associated control signals.
15. The particle beam apparatus of any of clause 11 to 14, wherein the data storage comprises a look-up table to obtain an appropriate control signal associated with a set-point signal, a derivative of the set-point signal, a position signal, a derivative of the position signal, and/or a magnetic field signal.
16. The particle beam apparatus of any of clause 3 to 15, wherein the controller further comprises a functional relationship between the set-point signals and/or the derivatives of the set-point signals, and the control signals to calculate an appropriate control signal upon input of a set-point signal and/or a derivative of the set-point signal.
17. The particle beam apparatus of clause 6 to 16, wherein the controller further comprises a further functional relationship between the position signals and/or the derivatives of the position signals, and the control signals to calculate a further appropriate control signal upon input of a position signal and/or a derivative of the position signal.
18. The particle beam apparatus of any of clause 10 to 17, wherein the controller further comprises an even further functional relationship between the control signals and magnetic field signals to calculate an even further appropriate control signal upon input of a magnetic field signal.
19. The particle beam apparatus of any of the preceding clauses, wherein the positioning device is configured to move the object table at least in a direction and wherein the at least one motor is arranged to compensate for a magnetic force on the object table at least in the direction.
20. The particle beam apparatus of any of the preceding clauses, wherein the positioning device is arranged to move the object table in six degrees of freedom.
21. The particle beam apparatus of any of the preceding clauses, wherein the positioning device comprises a long stroke stage and a short stroke stage, wherein the object table is supported by the short stroke stage and wherein the short stroke stage is supported by the long stroke stage, such that the long stroke stage is arranged to position the short stroke stage with respect to the particle beam and that the short stroke stage is arranged to position the object table with respect to the particle beam, wherein at least one motor of the short stroke stage is configured to be controlled at least partly based on the control signal.
22. The particle beam apparatus according to any of clause 3 to 21, further comprising a set-point generator to provide the set-point signal that is representative for the desired position of the object table.
23. The particle beam apparatus according to any of clause 6 to 22, further comprising a comparator to compare the further set-point signal with the position signal to provide an error signal, wherein the further controller is configured to provide the further control signal at least partly based on the error signal.
24. The particle beam apparatus of according to any of clause 4 to 23, further comprising an addition device configured to add the control signal and the further control signal.
25. The particle beam apparatus of any of the preceding clauses, further comprising at least one shielding comprising the ferromagnetic material, wherein the shielding is arranged to shield the particle beam at least partly from a magnetic field generated by the positioning device.
26. A method for positioning an object table of an particle beam apparatus, comprising the steps of:
   providing a control signal to compensate for a magnetic force induced by a magnetic field acting on a positioning device for positioning the object table, the magnetic field at least partly emitted from a magnetic lens of the particle beam apparatus,
   actuating at least one motor of the positioning device at least partly based on the control signal.
27. The method of clause 26, further comprising the steps of:
   generating a set-point signal that is representative for a desired position of the object table,
   wherein the step of providing the control signal is at least partly based on a set-point signal and/or a derivative thereof.
28. The method of clause 26 or 27, further comprising the steps of:
   determining a position signal representing a position of the object table,
wherein the step of providing the control signal is at least partly based on the position signal and/or a derivative thereof.
29. The method of any of clause 26 to 28, wherein the step of providing the control signal is at least partly based on a magnetic field signal.
30. The method of any of clause 26 to 29, further comprising the steps of:
providing a further control signal to position the object table; and
actuating the at least one motor of the positioning device at least partly based on the further control signal.
31. The method of clause 30, wherein the further control signal comprises a feed-forward control signal and/or a feed-back control signal.
32. The method of clause 30 or 31, wherein the step of providing the further control signal is at least partly based on a difference between the position signal and a further set-point signal.
33. The method of clause 32, wherein the further set-point signal is the same as the set-point signal.
34. The method of any of clause 26 to 33, wherein the step of providing the control signal uses a data storage comprising:
   set-point signals and/or derivatives of the set-point signals, and associated control signals;
   position signals and/or derivatives of the position signals, and associated control signals; and/or
   magnetic field signals and associated control signals.
35. The method of clause 34, wherein the step of providing the control signal comprises the step of interpolating a value between stored combinations of:
the set-point signals and/or derivatives of the set-point signals, and the associated control signals;
the position signals and/or derivatives of the position signals, and the associated control signals; and/or
the magnetic field signals and the associated control signals.
36. The method of clause 34, wherein the data storage comprises a look-up table to obtain an appropriate control signal associated with a set-point signal, a derivative of the set-point signal, a position signal, a derivative of the position signal, and/or a magnetic field signal.
37. The method of any of clause 26 to 36, wherein the step of providing the control signal uses a functional relationship describing:
set-point signals and/or derivatives of the set-point signals, and associated control signals;
position signals and/or derivatives of the position signals, and further associated control signals; and/or
magnetic field signals and even further associated control signals,
to calculate an appropriate control signal upon input of a set-point signal, a derivative of the set-point signal, a position signal, a derivative of the position signal, and/or a magnetic field signal.
38. The method of any of clause 26 to 37, wherein the at least one motor, with the control signal, is configured to compensate for a magnetic force induced by a magnetic field acting on the positioning device at least in a direction of motion of the object table.
39. The method of any of clause 26 to 38, wherein the positioning device comprises a long stroke stage and a short stroke stage, wherein the object table is supported by the short stroke stage and wherein the short stroke stage is supported by the long stroke stage, such that the long stroke stage is arranged to position the short stroke stage with respect to the particle beam and that the short stroke stage is arranged to position the object table with respect to the particle beam, wherein at least one motor of the short stroke stage is configured to be controlled at least partly based on the control signal.
40. The method of any of clause 30 to 39, wherein the step of actuating the at least one motor of the positioning device comprises the step of adding, with an addition device, the control signal and the further control signal.
41. A method for determining a control signal in a controller of an particle beam apparatus, comprising the steps of:
   moving an object table to a desired position;
   storing a set-point signal that is representative for the desired position and/or a derivative of the set-point signal;
   emitting a magnetic field;
   measuring a magnetic force that is induced by the magnetic field that acts on the object table, or an effect thereof; and
   determining a required control signal to compensate the magnetic force.
42. A method for determining a control signal in a controller of an particle beam apparatus, comprising the further steps of:
   moving an object table to a desired position;
   measuring a position of the object table;
   storing a position signal representing the position of the object table and/or a derivative of the position signal;
   emitting a magnetic field;
measuring a magnetic force that is induced by the magnetic field that acts on the object table, or an effect thereof; and
   determining a required control signal to compensate the magnetic force.
43. A method for determining a control signal in a controller of an particle beam apparatus, comprising the even further steps of:
   moving an object table to a desired position;
   emitting a magnetic field;
   storing a magnetic field signal that corresponds to a parameter of the magnetic field and/or an electric current through a magnetic coil emitting the magnetic field;
   measuring a magnetic force that is induced by the magnetic field that acts on the object table, or an effect thereof; and
   determining a required control signal to compensate the magnetic force.
44. The method of any of clause 41 to 43, further comprising, after the step of determining, the step of repeating the steps of emitting, storing the magnetic field signal, measuring the magnetic force and determining, for plurality of magnetic fields.
45. The method of any of clause 41 to 44, comprising the step of repeating all steps for plurality of desired positions.
46. The method of any of clause 41 to 45, wherein each of the set-point signals, each of the derivatives of the set-point signals, the position signals, the derivatives of the position signals, and/or the magnetic field signals are stored in a data storage with a respective associated control signal.
47. The method of clause 46, wherein the data storage comprises a look-up table.
48. The method of any of clause 41 to 47, further comprising the step of determining, with the controller, a functional relationship between the set-point signal and/or derivatives of the set-point signals, and the control signal, a further functional relationship between the position signal and/or derivatives of the position signals, and the control signal and/or an even further functional relationship between the magnetic field signal and the control signal.

Although the embodiments described in the specification are mainly related to an e-beam inspection tool or apparatus, the applications of this described embodiments may not be limited to these particular embodiments. The disclosed embodiments may be applied not only to the e-beam inspection tools but to any other kinds of e-beam tools such as CD-SEM, EBDW (E-Beam Direct Writer), EPL (E-beam Projection Lithography, and E-beam defect verification tool.

Although the present disclosed has been explained in relation to its preferred embodiments, it is to be understood that other modifications and variations can be made without departing the spirit and scope of the invention as hereafter claimed.

What is claimed is:

1. A particle beam apparatus comprising:
a particle beam source configured to generate a particle beam;
a magnetic coil configured to emit a magnetic field to manipulate the particle beam;
an object table configured to hold a substrate;
a positioning device comprising ferromagnetic material, the positioning device further comprising at least one motor configured to position the object table with respect to the particle beam; and
a controller configured to provide a control signal to the at least one motor to at least partly compensate for a magnetic force induced by the magnetic field acting on the positioning device.

2. The particle beam apparatus according to claim 1, wherein the magnetic force is a magnetic reluctance force induced by the magnetic field and/or a magnetic damping force induced by eddy current.

3. The particle beam apparatus according to claim 1, wherein the controller is configured to provide the control signal at least partly based on a set-point signal and/or a derivative of the set-point signal, the set-point signal representing a desired position of the object table.

4. The particle beam apparatus according to claim 1, further comprising:
a further controller configured to provide a further control signal to the at least one motor to position the object table.

5. The particle beam apparatus according to claim 1, the particle beam apparatus further comprising
a position measurement system to provide a position signal representing a position of the object table,
wherein the controller is configured to provide the control signal at least partly based on the position signal and/or a derivative of the position signal.

6. The particle beam apparatus according to claim 1, wherein the controller is configured to provide the control signal at least partly based on a magnetic field signal, the magnetic field signals being representative for a parameter of the magnetic field and/or an electric current through the magnetic coil.

7. The particle beam apparatus according to claim 1,
wherein the controller comprises a data storage configured to store:
set-point signals and/or derivatives of the set-point signals, together with associated control signals, the set-point signals representing a desired position of the object table;
position signals and/or derivatives of the position signals, together with further associated control signals, the position signal representing a position of the object table; and/or
magnetic field signals and even further associated control signals, the magnetic field signals being representative for a parameter of the magnetic field and/or an electric current through the magnetic coil,
or wherein the controller comprises a functional relationship between:
the set-point signal and/or a derivative of the set-point signal, and the control signal to calculate an appropriate control signal upon input of a set-point signal and/or a derivative of the set-point signal;
the position signal and/or a derivative of the position signal, and the control signal to calculate a further appropriate control signal upon input of a position signal and/or a derivative of the position signal; and/or
the control signal and the magnetic field signal to calculate an even further appropriate control signal upon input of a magnetic field signal.

8. The particle beam apparatus of any of claim 7, wherein the data storage comprises a look-up table to obtain an appropriate control signal associated with a set-point signal, a derivative of the set-point signal, a position signal, a derivative of the position signal, and/or a magnetic field signal.

9. The particle beam apparatus according to claim 1, further comprising at least one shielding comprising the ferromagnetic material, wherein the shielding is arranged to at least partly shield the particle beam from a magnetic field generated by the positioning device.

10. A method for positioning an object table of an particle beam apparatus, comprising the steps of:
providing a control signal to compensate for a magnetic force induced by a magnetic field acting on a positioning device for positioning the object table, the magnetic field at least partly emitted from a magnetic coil of the particle beam apparatus,
actuating at least one motor of the positioning device at least partly based on the control signal.

11. The method of claim 10, further comprising the steps of:
generating a set-point signal that is representative for a desired position of the object table,
wherein the step of providing the control signal is at least partly based on a set-point signal and/or a derivative thereof.

12. The method of claim 10, further comprising the steps of:
determining a position signal that is representative for a position of the object table,
wherein the step of providing the control signal is at least partly based on the position signal and/or a derivative thereof.

13. The method of claim 10, wherein the step of providing the control signal is at least partly based on a magnetic field signal.

14. The method of claim 10, wherein the step of providing the control signal uses a data storage comprising:
set-point signals and/or derivatives of the set-point signals, together with associated control signals, the set-point signals representing a desired position of the object table;
position signals and/or derivatives of the position signals, together with further associated control signals, the position signal representing a position of the object table; and/or
magnetic field signals and even further associated control signals, the magnetic field signals being representative for a parameter of the magnetic field and/or an electric current through the magnetic coil,
or wherein the step of providing the control signal uses a functional relationship describing:
the set-point signal and/or a derivative of the set-point signal, and the control signal;
the position signal and/or a derivative of the position signal, and the control signal; and/or
the magnetic field signals and the even further associated control signals,
to calculate an appropriate control signal upon input of a set-point signal, a derivative of the set-point signal, a position signal, a derivative of the position signal, and/or a magnetic field signal.

15. A non-transitory computer readable storage medium storing instructions which, when executed by a computer, cause the computer to perform the method according to claim 10.
